(19) United States
(12) Patent Application Publication
(10) Pub. No.: US 2010/0277684 A1
(43) Pub. Date: Nov. 4, 2010

(54) DISPLAY DEVICE AND METHOD FOR PRODUCTION THEREOF

(76) Inventors: Hiroshi Fukushima, Osaka (JP); Tomoo Takatani, Osaka (JP)

Correspondence Address: BIRCH STEWART KOLASCH & BIRCH, PO BOX 747, FALLS CHURCH, VA, 22040-0747, US

(21) Appl. No.: 12/681,949

(22) PCT Filed: Jul. 10, 2008
(86) PCT No.: PCT/JP2008/062509

§ 371 Date: Apr. 7, 2010

(30) Foreign Application Priority Data
Oct. 22, 2007 (JP) 2007-274345

(51) Int. Cl. G02F 1/1333; H05K 7/00; H05B 33/02; B29C 65/14

(52) U.S. Cl. 349/158; 361/679.01; 313/358; 156/275.5

(57) ABSTRACT

The present invention provides a display device in which the adhesive for bonding the display panel and the substrate to each other is prevented from remaining as an uncured portion, and a method for production thereof. The present invention provides: a display device comprising a display panel, a substrate disposed on a display side, and an adhesive layer via which the display panel and the substrate are bonded to each other, wherein the adhesive layer contains a cationically polymerized resin; and the method for production thereof. The adhesive layer more preferably has a refractive index corresponding to that of a member adjacent to the adhesive layer.

### TECHNICAL FIELD

The present invention relates to display devices and methods for production thereof. The present invention more specifically relates to a display device suitably used as display devices for portable terminals such as mobile phones, PDAs (Personal Digital Assistants), PDA phones, handheld game consoles, and tablet PCs (Personal Computers), and methods for production thereof.

### BACKGROUND ART

Flat panel displays (hereinafter, also referred to as “FPDs”), which can be made thin, have recently been widespread as display devices for televisions, personal computers, and portable terminals. Examples of the FPDs currently in practical use include liquid crystal display devices and plasma display panels (PDPs). Examples of the FPDs which are expected to be in practical use and widespread in future include organic electroluminescent display devices (hereinafter, also referred to as “organic EL displays”) and field emission displays (hereinafter, also referred to as “FEDs”).

In particular, among these FPDs, the liquid crystal display panels are easily made thin, are easily allowed to consume lower power, and are applicable for a wide range of display sizes, from a small size to a large size. Thus, the liquid crystal display devices are used in various applications such as televisions, displays for personal computers, and displays for portable terminals. In a common liquid crystal display device, liquid crystal is interposed between a pair of substrates and is electrically aligned, and the amount of light from a backlight is controlled to display an image.

In the field of the portable terminals such as mobile phones, PDAs, PDA phones, handheld game consoles, and tablet PCs, display devices each provided with a cover substrate (hereinafter, also referred to as a “first conventional display device”) are developed. The cover substrate is disposed on the display side of a display panel so as to protect the display side of the display panel and to provide better appearance to the portable terminal.

In the same field, display devices in each of which a display panel and a cover substrate are bonded to each other via an adhesive made of resin (hereinafter, also referred to as a “second conventional display device”) are developed.

For example, Patent Document 1 discloses an electrooptic apparatus including a first substrate, a second substrate, and an electrooptic material sandwiched between the substrates, wherein a third substrate is bonded to at least one of the first substrate and the second substrate via an adhesive, and grooves are formed on at least one of areas: an area existing on the bonding side of at least one of the first substrate and the second substrate and facing to the third substrate; and an area existing on the bonding side of the third substrate and facing to at least one of the substrates.

In the field of optical recording media, for example, Patent Document 2 discloses an optical recording medium including: a first disk in which an organic dye-containing recording layer, a metal reflecting layer, and a protecting layer are successively laminated on a first substrate; a second disk in which a metal reflecting layer and a protecting layer are successively laminated on a second substrate; and an adhesive layer made of a slowly cured and cationically polymerized resin via which the first and second substrates are bonded to each other so that the protecting layers face to each other.

### [Patent Document 1]

Japanese Kokai Publication No. 2006-58605

### [Patent Document 2]

Japanese Kokai Publication No. H11-86344

### DISCLOSURE OF INVENTION

In the first conventional display device, the cover substrate is attached to the display panel with a double-sided tape or held on a cabinet of the display device. This problematically forms an air layer between the cover substrate and the display panel. Thus, interfacial reflection occurs at the interface between the cover substrate and the air layer or between the display panel and the air layer, resulting in decrease in transmissivity of the display panel. Further, reflection of the outside light occurs at the interface of the air layer, resulting in decrease in display contrast. In addition, the first conventional display device has poor vibration resistance and impact resistance, which are required to be improved.

According to the second conventional display device and the technique disclosed in Patent Document 1, the adhesive can be made of a resin having a refractive index corresponding to that of a member of the cover substrate and the display panel. This results in increase in transmissivity of the display panel and inhibition of decrease in display contrast due to the outside light. Further, as the cover substrate and the display panel are almost entirely bonded to each other by the adhesive, the display device can have better vibration resistance and impact resistance.

The cover substrate is commonly placed at the outermost portion of the display device and has a great influence on the appearance of a product. Thus, in many cases, alight shielding portion such as a black edge portion is formed so as to provide a better design to the product. In such cases, the second conventional display device and the technique disclosed in Patent Document 1 are likely to have poor productivity and reliability.

The following will describe in more detail, referring to FIG. 7, the cause of the deterioration in productivity and reliability of the display device in the cases of forming the light shielding portion on the cover substrate. Here is described is the case of bonding a cover substrate 130 provided with a window portion 132 as a light transmitting portion and a black edge portion 131 as a light shielding portion to a liquid crystal display panel 110. FIGS. 7(a) to 7(c) each are a schematic cross-sectional view showing a display device of a comparative embodiment in the production process. FIG. 8 is an enlarged schematic cross-sectional view showing the area enclosed by the dot line in FIG. 7(c), that is, the vicinity of an end portion of an adhesive layer in the display device of the comparative embodiment.

In the bonding of the cover substrate 130 to the liquid crystal display panel 110, an adhesive 120 mainly made of a radically polymerizable resin is first applied to a polarizing plate 113a disposed on the display side of the liquid crystal display panel 110 with a nozzle 140 such as a slit coater, as shown in FIG. 7(a). Here, the liquid crystal display panel 110 includes, in addition to the polarizing plate 113a, a TFT array substrate 111, a CF substrate 112, and a polarizing plate 113b disposed on the back side, and the TFT array substrate 111 is coupled with a FPC substrate 114. Examples of the adhesive 120 include a UV-curable resin (EXS-57H, produced by Dainippon Ink and Chemicals, Corp.). This UV-curable resin is a colorless, transparent urethane acryl resin and has a viscosity of 1300 cP at 23° C. Next, as shown in FIG. 7(b), the liquid crystal display panel 110 and the cover substrate 130 are bonded and aligned with each other. Then, as shown in FIG. 7(c), the adhesive 120 is irradiated with ultraviolet light 150 through the cover substrate 130 at an integrated light quantity of 1500 to 5000 mJ/cm². Thereby, the adhesive 120 is cured and the liquid crystal display panel 110 and the cover substrate 130 are fixed to each other.

When the adhesive 120 is irradiated with the ultraviolet light 150 through the cover substrate 130, the ultraviolet light 150 sufficiently passes through the transparent window 132 as shown in FIG. 8. Thus, the adhesive 120 located below the window portion 132 is efficiently and sufficiently cured to be an adhesive layer 121 (cured adhesive). On the other hand, the ultraviolet light 150 is not allowed to pass through the opaque black edge portion 131. Thus, the adhesive located below the black edge portion 131 is not irradiated with the ultraviolet light 150 and remains as an uncured portion (uncured content). In other words, the adhesive 120 is cured only at the portion irradiated with the ultraviolet light 150.

A radical species, which serves as an active species for polymerization of the radically polymerizable resin, easily reacts with oxygen in the air. Thus, the adhesive is insufficiently polymerized at the portion contacting with oxygen in the air, and also remains as the uncured portion.

When the uncured portion remains in the adhesive bonding the substrate such as the cover substrate and the display panel such as the liquid crystal display panel to each other, a cleaning process may be required, resulting in poor productivity. When the cleaning is insufficient, products left under high temperature conditions may generate bad smell due to volatilization of the uncured portion and the cover substrate may be come off, resulting in poor reliability.

The present invention is devised considering the aforementioned situations. The present invention is to provide the display device in which an uncured portion is prevented from remaining in the adhesive for bonding the display panel and the substrate to each other, and the method for production thereof.

The present inventors have performed various studies on display devices such that an uncured portion is prevented from remaining in the adhesive for bonding the display panel and the substrate to each other and methods for production thereof. Then, the present inventors have focused on materials of the adhesive, and thereby found the following advantages. The advantages are that: a cationically polymerizable resin-containing adhesive, that is, a cationically polymerized resin-containing adhesive layer which is formed by curing of the adhesive, allows the display panel and the substrate to be bonded to each other after irradiation of the ultraviolet light to the adhesive; and the adhesive is allowed to cure while preventing inhibition of polymerization of the cationically polymerizable resin by oxygen. Thus, the present inventors have found the solution of the aforementioned problems, and thereby arrived at the present invention.

The present invention provides a display device including a display panel, a substrate disposed on the display side, and an adhesive layer via which the display panel and the substrate are bonded to each other, wherein the adhesive layer contains a cationically polymerized resin. The cationically polymerized resin is formed in a catalytic system, contrasted with radically polymerizable resins. Once the polymerization is triggered, for example, by light irradiation, the cationically polymerizable resin can continue to polymerize even after the light irradiation is stopped. That is, the cationically polymerizable resin has dark reactivity. Further, the cationically polymerizable resin is slowly polymerized, and thus the adhesive, which is a material of the adhesive layer containing the cationically polymerized resin, is allowed to slowly cure. In other words, the adhesive has slow curability. Thus, the display panel and the substrate are allowed to be bonded to each other after irradiation of light to the adhesive in the production process of the display device of the present invention. That is, the adhesive is allowed to be irradiated with light at almost the entire exposed surface before bonding the display panel and the substrate. This results in uniform curing of the whole adhesive even though the substrate has a light shielding portion. In addition, the cationically polymerizable resin is not prevented by oxygen from polymerizing. Thus, an uncured portion is prevented from remaining in the adhesive due to oxygen, contrasted with the case of using radically polymerizable resin-containing adhesives. As mentioned above, the display device of the present invention prevents the adhesive from remaining as an uncured portion, and thereby the display device of the present invention is allowed to have better reliability. Further, the cleaning process for removing an uncured portion of the adhesive is not required, and thereby the display device of the present invention is allowed to be produced in better productivity.

The configuration of the display device of the present invention is not especially limited as long as it essentially includes such components. The display device may or may not include other components.

Preferable embodiments of the display device of the present invention are mentioned in more detail below. The following embodiments may be employed in combination.

For surely and sufficiently exerting the effects of the present invention, the adhesive, which is a material of the adhesive layer, preferably has slow curability and is preferably a photocurable adhesive; the cationically polymerized resin is preferably formed in dark reaction; and the display device of the present invention more preferably has all of the above features.

The adhesive layer is preferably colorless and transparent. A colored adhesive layer may provide colored display images to an observer. An adhesive layer having hazes such as cloudiness may provide blurred display images to an observer. Thus, the display device of the present aspect can more clearly display images as light from the display panel can be effectively prevented from being colored and shielded by the adhesive layer.

The adhesive layer preferably has a refractive index corresponding to that of a member adjacent to the adhesive layer. This prevents reduction in brightness of the display device due to interfacial reflection between the substrate and the adhesive layer and between the display panel and the adhesive layer. Thereby, the display device of the present invention can have better display quality. The term “corresponding” herein means that the refractive indexes are adjusted so as to exert the aforementioned effect, and they may be thoroughly the same as each other or may be substantially the same as each other.

The adhesive layer may further contain a radically polymerized resin. The adhesive layer containing a rapidly cured and radically polymerized resin can lead to a shorter curing time period of the adhesive. Thus, the display device of the present invention can be produced in better productivity.

The cationically polymerized resin may be formed by thermal curing. That the cation polymerized resin is formed by thermal curing means the adhesive layer can be formed in a shorter time period. Thus, the display device of the present invention can be produced in better productivity.

The substrate may have a light shielding portion at an area to which the adhesive layer is attached. In the case of the conventional display device in which the substrate and the display panel are bonded to each other via the radically polymerizable resin-containing adhesive and the light shielding portion is formed on the substrate, the adhesive remains as an uncured portion at the portion covered with the light shielding portion as mentioned above. Thus, it is difficult to freely provide a light shielding portion on the substrate for retaining reliability. That is, the conventional display device may have limitation on the design of the substrate. On the other hand, in the display device of the present invention, the adhesive can be sufficiently cured even at the portion covered with the light shielding portion as mentioned above. Thus, the substrate can be freely designed. Therefore, in the case where the substrate in the present invention has the light shielding portion at the bonding site to the adhesive layer, the display device having more excellent appearance while retaining reliability can be provided.

The substrate may be a cover substrate. A cover substrate is commonly located at the outermost portion of the display side. Thereby, the display device having more excellent appearance can be provided.

The display panel in the present invention may be a liquid crystal display panel or an organic electroluminescent display panel. Thereby, the display device of the present invention can be suitably used in portable terminals.

The present invention also provides a method for producing the display device of the present invention. The production method includes: applying an adhesive, which is a material of the adhesive layer, to at least one of the display panel and the substrate; irradiating light to the adhesive; and bonding the display panel and the substrate to each other via the light-irradiated adhesive. Thereby, the display device of the present invention can be easily produced.

The production method of the display device according to the present invention is not especially limited as long as these steps are included. The production method may include other steps.

Preferable embodiments of the production method of the display device of the present invention are mentioned in more detail below. The following embodiments may be employed in combination.

The method for producing the display device may further include irradiating light to the adhesive after bonding the display panel and the substrate (hereinafter, such an aspect is also referred to as a “first aspect”). This aspect allows the adhesive to cure in a shorter time period and the display device of the present invention to be produced in better productivity. In addition, this aspect enables easier fixing of the display panel and the substrate after the alignment thereof.

In the first aspect, the method for producing the display device may include: the first irradiation step of light to the adhesive applied to at least one of the display panel and the substrate; the bonding step of the display panel and the substrate to each other after the first irradiation step; and the second irradiation step of light to the adhesive again after the bonding step. Thereby, the first aspect can be more easily carried out.

The method for producing the display device may further include heating the adhesive after bonding the display panel and the substrate to each other (hereinafter, such an aspect is also referred to as a “second aspect”). This aspect also allows the adhesive to cure in a shorter time period and the display device of the present invention to be produced in better productivity.

In the second aspect, the method for producing the display device may include: the first irradiation step of light to the adhesive applied to at least one of the display panel and the substrate; the bonding step of the display panel and the substrate to each other after the first irradiation step; and the heating step of the adhesive after the bonding step. Thereby, the second aspect can be more easily carried out.

### EFFECT OF THE INVENTION

The display device of the present invention and the method for production thereof prevent an uncured portion from remaining in the adhesive via which the display panel and the substrate are bonded to each other.

### BEST MODES FOR CARRYING OUT THE INVENTION

The present invention is mentioned in more detail below with reference to Embodiments using drawings, but not limited thereto.

### Embodiment 1

FIGS. 1 are a schematic cross-sectional view showing a display device of Embodiment 1. FIG. 1(a) is a general view. FIG. 1(b) is an enlarged view showing the area enclosed by the dot line in FIG. 1(a), that is, the vicinity of an end portion of an adhesive layer. FIG. 2 is a schematic plane view showing a cover substrate of Embodiment 1. FIG. 3 is a schematic plane view showing a liquid crystal display panel of Embodiment 1.

As shown in FIG. 1(a), a display panel 100 of the present embodiment includes: a liquid crystal display panel 10; a cover substrate 30 disposed on the display side of the liquid crystal display panel 10; an adhesive layer 21 interposed between the liquid crystal display panel 10 and the cover substrate 30; a backlight unit (not shown) disposed on the back side of the liquid crystal display panel 10; and a cabinet (not shown) for holding these components. In the display device 100, the liquid crystal display panel 10 and the cover substrate 30 are bonded, i.e., adhered (fixed) to each other via the adhesive layer 21.

The liquid crystal display panel 10 includes a TFT array substrate 11 and a color filter substrate (CF substrate) 12, which face each other, and a sealing material disposed along the outline of the CF substrate 12. The space defined by the TFT array substrate 11, the CF substrate 12, and the sealing material is filled with a liquid crystal material. Thus, a liquid crystal layer is interposed between the TFT array substrate 11 and the CF substrate 12. The sealing material is used for sealing the liquid crystal layer between the TFT array substrate 11 and the CF substrate 12, and is disposed on the area other than the area for displaying images, namely, the non-display area (edge area). The sealing material and the liquid crystal layer each may be made of any appropriately selected material.

The TFT array substrate 11 is provided with components of the display element in the liquid crystal display panel 10 at the side of the liquid crystal layer of a colorless, transparent insulating substrate. The components disposed to the TFT array substrate 11 include a thin film transistor (TFT) as a switching element, a pixel electrode, a bus wiring such as a data wiring and a scan wiring, and an alignment layer. As shown in FIGS. 1(a) and 3, the TFT array substrate 11 has a projecting portion from the CF substrate 12. The projecting portion is provided with a terminal and is coupled with an FPC substrate 14 on which a driver and other components are mounted. As mentioned here, the liquid crystal display panel 10 is an active matrix liquid crystal display panel with pixels arranged in a matrix.

The CF substrate 12 is provided with components such as a black matrix (BM), red, blue, and green color filters, a common electrode, and an alignment film at the side of the liquid crystal layer of a colorless, transparent insulating substrate.

The insulating film may be made of any material. Preferable examples of the material include glass and resin (plastic) owing to their excellent light transmissivity and processability.

The CF substrate 12 and the TFT array substrate 11 each are provided with polarizing plates 13a and 13b, respectively, at the main surface of the outside (the side opposite to the liquid crystal layer). The polarizing plates 13a and 13b each include a polarizer formed of a PVA (polyvinyl alcohol) film with an iodine complex or a dichromatic dye adsorbed thereon and protecting layers each formed of a cellulose polymer such as triacetyl cellulose (TAC). The polarizer is sandwiched between the protecting layers. A viewing angle compensation film such as a retardation plate may be disposed between the TFT array substrate 11 and the polarizing plate and/or between the CF substrate 12 and the polarizing plate.

The cover substrate 30 protects the display panel 10 from dust, impact, and the like, and is disposed so as at least to cover the display area. The cover substrate 30 disposed in the display device 100 allows the display device 100 to have better appearance.

The cover substrate 30 is transparent at least at the area corresponding to the display area. More specifically, the cover substrate 30 has a window portion 32 which is a light transmitting portion formed corresponding to the display area and a black edge portion 31 which is a light shielding portion formed around the window portion, as shown in FIG. 1. This allows the display device 100 to have better appearance and allows the cover substrate 30 to effectively cover the portion which ought to be covered of the liquid crystal display panel 100.

The window portion 32 of the cover substrate 30 may be colorless or may be colored. In the case of a colorless window portion 32, the display device 100 can display an image displayed on the liquid crystal display panel 10 in the same color tones. In the case of a colored window portion 32, the display device 100 can display an image displayed on the liquid crystal display panel 10 in bluish tones or reddish tones, for example.

The cover substrate 30 may have any plane shape. Examples of the plane shape include a rectangular shape, an elliptical shape, a rectangular shape with rounded corners, and a combination shape of a rectangle and an ellipse. In addition, the window portion 32 and the black edge portion 31 each may have any plane shape. The plane shapes thereof may be appropriately configured according to desired designs.

The adhesive layer 21 is disposed on almost the entire areas at which the liquid crystal display panel 10 and the cover substrate 30 face each other. This allows the display device 100 to have better vibration resistance and impact resistance. As shown in FIG. 1(b), the adhesive layer 21 is also disposed between the black edge portion 31 and the liquid crystal display panel 10 as well as between the window portion 32 and the liquid crystal display panel 10. The adhesive layer 30 is a colorless, transparent layer formed by curing the adhesive. Thus, an observer is allowed to more clearly recognize an image displayed on the liquid crystal display panel 10. The adhesive layer 30 preferably has a haze of 3% or less (more preferably 1% or less).

The adhesive layer 21 contains a cationically polymerized resin. The cationically polymerized resin is formed by chain polymerization of monomers or oligomers with a cation serving as an active species, and by dark reaction. As mentioned here, the cationically polymerized resin contained in the adhesive layer 21 is also a UV-cured resin initiated to polymerize by UV irradiation. Further, the adhesive, which is a material of the adhesive layer 21, is a UV-curable adhesive which is initiated to cure by UV irradiation. The cationically polymerizable resin-containing adhesive has slow curability, and the polymerization (curing) thereof takes a certain time period from the start to the end. Thus, the cationically polymerizable resin-containing adhesive is allowed to cure more slowly than the radically polymerizable resin-containing adhesive. Further, the cationically polymerizable resin is not prevented from polymerizing by oxygen, in contrast to the radically polymerizable resin. These characteristics prevent an uncured portion from remaining in the adhesive layer 21 through the below-mentioned production process. The cationically polymerized resin contained in the adhesive layer 21 may be a light-cured resin, and the adhesive, which is a material of the adhesive layer 21, may be a photocurable adhesive.

A resin such as the cationically polymerizable resin generally has a higher light transmissivity than the air. Thus, the adhesive layer 21 mainly containing a resin allows the liquid crystal display device 100 to have better light transmissivity.

The adhesive layer 21 has a refractive index corresponding to that of the material (glass, resin, etc.) of the cover substrate 30 and that of the protecting layer of the polarizing plate 13a. Specifically, the refractive indexes of the adhesive layer 21, the cover substrate 30, and the protecting layer of the polarizing plate 13a are adjusted to about 1.48 to 1.52. Thereby, light reflection is inhibited at the interfaces between the adhesive layer 21 and the liquid crystal display panel 10 and between the adhesive layer 21 and the cover substrate 30. Thus, the display device 100 is allowed to have higher light transmissivity and its display contrast is not impaired by the outside light. The difference between the refractive indexes of the adhesive layer 21 and a member adjacent to the adhesive layer 21 is preferably 0.04 or less.

The distance between the liquid crystal display panel 10 and the cover substrate 30, namely, the thickness of the adhesive layer 21 is adjusted to be 50 μm or thicker (more preferably, 100 μm or thicker). The adhesive layer 21 having such a thickness effectively serves as a buffer layer for lessening pressure and impacts. Thus, the liquid crystal display panel 10 is not directly affected by finger pressure applied from the side of the cover substrate 30 or by impact generated when an object is dropped on the cover substrate 30.

The adhesive layer 21 is adjusted to have a storage modulus of 1.0×10³ to 1.0×10⁶ Pa at 23° C. In the case of a resin-containing adhesive, the adhesive layer is likely to unevenly contract between a peripheral portion and an inner central portion thereof as the adhesive is cured, and thereby inner stress is likely to generate in the adhesive layer. This may have an influence on the cell thickness of the liquid crystal display panel, resulting in display unevenness at an edge portion of the display area. Here, in the present embodiment, the adhesive layer 21 is adjusted to have the aforementioned storage modulus, so that the adhesive layer 21 absorbs the inner stress owing to its elasticity. Thereby, the display device 100 is allowed to have better display quality.

The following will describe a method for producing the display device of Embodiment 1 referring to FIG. 4. FIGS. 4(a) to 4(c) each are a schematic cross-sectional view showing the display device of Embodiment 1 in the production process.

First, the liquid crystal display panel 10 is prepared by a common method. The liquid crystal display panel 10 may have any liquid crystal mode, and examples of the liquid crystal mode include a TN (Twisted Nematic) mode, an IPS (In Plane Switching) mode, and a VATN (Vertical Alignment Twisted Nematic) mode. The liquid crystal display panel 10 may be a multi-domain liquid crystal display panel. The liquid crystal display panel 10 may be of a transmissive type, a reflective type, or a transreflective type (combination of the reflective and transmissive types). The reflective liquid crystal display panel 10 is not required to be provided with a backlight unit. The polarization axes of the polarizing plates 13a and 13b are arranged depending on the liquid crystal mode. The polarizing plates 13a and 13b are generally arranged in crossed Nicols or parallel Nicols. The liquid crystal display panel 10 is connected to an FPC substrate 14 to provide a liquid crystal display module.

Then, the cover substrate 30 having the window portion 32 and the black edge portion 31 is prepared. The material of the cover substrate 30 is not particularly limited as long as it has a measure of strength and is transparent. The material is preferably glass or resin. The black edge portion 31 may be formed by any method, and is preferably formed by printing black ink on the main surface of the cover substrate 30 on the side of the adhesive layer 21. The cover substrate 30 may have another edge portion with color other than black or with a plurality of colors. The color of the black edge portion 31 is not limited to black, and may be appropriately designed depending on a predetermined appearance.

As shown in FIG. 4(a), an adhesive 20a is applied to the polarizing plate 13a of the liquid crystal display panel 10 with a nozzle 40 of an applying apparatus such as a slit coater so that the thickness of the applied adhesive is about 50 to 200 μm. The adhesive 20a may be applied to the cover substrate 30 or may be applied to both of the polarizing plate 13a and the cover substrate 30. Commonly, the adhesive 20a is applied to either of the polarizing plate 13a or the cover substrate 30. The adhesive 20a is a material of the adhesive layer 21, and the adhesive 20a is cured to be the adhesive layer 21. The adhesive 21a contains a cationically polymerizable resin and is a UV-curable adhesive having dark reactivity and slow curability. The degree of slow curability of the adhesive 21a is not particularly limited. It is preferable that curing of the adhesive is completed after the finish of bonding and alignment of the substrate. More specifically, the curing preferably takes about 8 to 10 minutes (more preferably about 2 to 3 minutes) from the start to the end. The adhesive 21a may be any cationically polymerizable resin-containing adhesive commonly used in the electronic or optical device field. Examples thereof include a UV-curable resin (Exp MR-5, produced by Dainippon Ink and Chemicals, Corp.). This UV-curable resin is a colorless, transparent urethane resin and has a viscosity of about 1800 cP at 23° C. The cationically polymerizable resin contained in the adhesive 21a is not particularly limited as long as it is usable as adhesive. Examples thereof include urethane acryl resins and epoxy resins, in addition to urethane resins.

As shown in FIG. 4(b), the entire exposed surface of the adhesive 20a is irradiated with ultraviolet light 50 from a light source lamp such as a metal halide lamp at an integrated light quantity of about 100 to 1500 mJ/cm². Thereby, a cation, which serves active species, is generated from an initiator contained in the cationically polymerizable resin to initiate polymerization, namely, curing of the adhesive 20a. Examples of the initiator commonly contained in the cationically polymerizable resin include a Bronsted acid or a Lewis acid such as aluminum trichloride. Further, the cationically polymerizable resin has dark reactivity and slow curability, so that the display panel 10 and the cover substrate 30 are allowed to be bonded to each other after the direct irradiation of a small amount of the ultraviolet light 50 to the adhesive 20a. This prevents the adhesive 20a from remaining as an uncured portion at the portion corresponding to the black edge portion 31 of the cover substrate 30. Furthermore, the polymerization of the cationically polymerizable resin is not inhibited by oxygen, so that an uncured portion is effectively prevented from remaining in the adhesive 20a even in the case of UV irradiation under atmospheric pressure.

As shown in FIG. 4(c), the cover substrate 30 is bonded to the liquid crystal display panel 10 via the adhesive 20a under atmospheric pressure or a reduced pressure at 10 Pa or lower. Then, the cover substrate 30 is pressurized with a pressurizing means, and thereby the liquid crystal display panel 10 and the cover substrate 30 are allowed to have a preferable distance between them. The pressure to be applied is not particularly limited, and may be about 50 kPa, for example. Then, the cover substrate 30 is shifted in a horizontal direction with an alignment means such as a chuck so as to align the liquid crystal display panel 10 and the cover substrate 30. The liquid crystal display panel 10 and the cover substrate 30 each are held at an appropriate position for about 10 minutes until the adhesive 20a is entirely cured. Thereby, the cover substrate 30 is fixed to the liquid crystal display panel 10.

The liquid crystal display module in which the cover substrate 30 is bonded to the liquid crystal display panel 10, a backlight unit, a cabinet, and other components are assembled with one another to provide the display device 100. The backlight unit may include general components such as a light source, a reflecting plate, and optical sheets. Further, the backlight unit may be of direct type or may be of edge light type.

As described hereinabove, in the present embodiment, the adhesive 20a contains the cationically polymerizable resin. This prevents the adhesive layer 20 from having an uncured portion, resulting in better reliability and productivity of the display device 100.

In the present embodiment, the adhesive 20a may be irradiated with ultraviolet light before and after the bonding. More specifically, such a process is performed as follows: the adhesive 20a is applied to the polarizing plate 13a of the liquid crystal display panel 10 in the same manner as mentioned above; the entire surface of the adhesive 20a is irradiated with the ultraviolet light 50 by a light source lamp such as a metal halide lamp at an integrated light quantity of about 1000 to 2000 mJ/cm² (the first irradiation); the display panel 10 and the cover substrate 30 are bonded to each other in the same manner as mentioned above; the liquid crystal display panel 10 and the cover substrate 30 are aligned in the same manner as mentioned above; while the liquid crystal display panel 10 and the cover substrate 30 each are held at an appropriate position, the adhesive 20a is again irradiated with the ultraviolet light 50 by a light source lamp such as a metal halide lamp through the cover substrate 30 at an integrated light quantity of about 3000 to 4000 mJ/cm² (the second irradiation); the liquid crystal display panel 10 and the cover substrate 30 each are held at an appropriate position for about 10 minutes until the adhesive 20a is entirely cured; and thereby the liquid crystal display panel 10 and the cover substrate 30 are fixed to each other. As mentioned here, the irradiation of a small amount of the ultraviolet light in the first irradiation and the further irradiation thereof in the second irradiation make it easier to fix the display panel 10 and the cover substrate 30 after the alignment.

The display device 100 of the present embodiment may include, instead of the liquid crystal display panel 10, an organic EL panel, a PDP panel, or a FED panel as the display panel. In other words, the display device 100 may be an organic EL display, a FPD, or a FED. In particular, the display device 100 is preferably a liquid crystal display device or an organic EL display. This allows the display device 100 to be suitably used as a portable terminal.

As mentioned above, the display panel of the display device 100 may be any display panel in which a display area is formed by pixels arranged in a matrix. Thus, the driving mode of the liquid crystal display panel 10 may be of passive matrix type.

In the case of applying an organic EL display to the display panel of the display device 100, the display panel of the display device 100 may be prepared with a display element formed of components such as electrodes and an organic thin film including a light emitting material, instead of the display element including a liquid crystal.

In the case of applying a PDP panel to the display panel of the display device 100, the display panel of the display device 100 may be prepared with a display element including components such as electrodes, a dielectric substance, a rare gas, and a phosphor, instead of the display element including a liquid crystal.

In the case of applying a FED to the display panel of the display device 100, the display panel of the display device 100 may be prepared with a display element including components such as a microchip, a gate electrode, and a phosphor, instead of the display element including a liquid crystal.

### Embodiment 2

The following will describe the display device of Embodiment 2 referring to FIG. 5. The contents of Embodiment 2 overlapping with those of Embodiment 1 are not described here.

The display device of the present embodiment has the same structure as that of Embodiment 1. Further, the adhesive layer of the present embodiment contains a radically polymerized resin in addition to the cationically polymerized resin. The radically polymerized resin is formed by chain polymerization of monomers or oligomers with a radical serving as an active species. A radical has a higher reactivity than a cation, and therefore the radically polymerized resin is formed by entire curing in a shorter time period than the cationically polymerized resin is. Thus, the adhesive, which is a material of the adhesive layer, of the present embodiment is cured in a shorter time period than in Embodiment 1, so that the display device is produced in better productivity.

The following will describe a method for producing the display device of Embodiment 2 referring to FIG. 5. FIGS. 5(a) to 5(d) each is a schematic cross-sectional view showing the display device of Embodiment 2 in the production process.

In the same manner as in Embodiment 1, the liquid crystal display panel 10 and the cover substrate 30 having the window portion 32 and the black edge portion 31 are prepared.

As shown in FIG. 5(a) and in the same manner as in Embodiment 1, an adhesive 20b is applied to the polarizing plate 13a of the liquid crystal display panel 10 with the nozzle 40 of an applying apparatus such as a slit coater so that the thickness of the applied adhesive is about 50 to 200 μm. Here, the adhesive 21b is a UV-curable adhesive containing the cationically polymerizable resin and the radically polymerizable resin. This accelerates curing of the adhesive 20b and shortens the curing time period of the adhesive 20b, that is, the time period required for the fixing of the cover substrate 30 and the liquid crystal display panel 10 via the adhesive 20b. The ratio of the cationically polymerizable resin and the radically polymerizable resin is not particularly limited and may be appropriately adjusted. The adhesive 20b preferably contains 5 to 30 wt % of the radically polymerizable resin to the amount of the cationically polymerizable resin. If the adhesive 20b contains the radically polymerizable resin in a ratio of more than 30 wt %, slow curability of the adhesive 20a may be deteriorated and the adhesive 20a is likely to cure before the bonding of the liquid crystal display panel 10 and the cover substrate 30. If the adhesive 20b contains the radically polymerizable resin in a ratio of less than 5 wt %, the radically polymerizable resin may fail to accelerate the curing of the adhesive 20b. Preferably used as such an adhesive 21b are mixtures of a cationically polymerizable resin-containing adhesive commonly used in the electronic or optical device field and a radically polymerizable resin-containing adhesive commonly used in the same field. More specific examples of the cationically polymerizable resin-containing adhesive include the same UV-curable resin as in Embodiment 1 (Exp MR-5, produced by Dainippon Ink and Chemicals, Corp.). Exp MR-5 is a colorless, transparent urethane resin and has a viscosity of about 1800 cP at 23° C. More specific examples of the radically polymerizable resin-containing adhesive include a UV-curable resin (EXS-57H, produced by Dainippon Ink and Chemicals, Corp.). EXS-57H is a colorless, transparent urethane acryl resin and has a viscosity of about 1300 cP at 23° C. The cationically polymerizable resin contained in the adhesive 21b is not particularly limited as long as it is usable as adhesive. Examples of the cationically polymerizable resin contained in the adhesive 21b include urethane acryl resins and epoxy resins, in addition to urethane resins. Also, the radically polymerizable resin contained in the adhesive 21b is not particularly limited as long as it is usable as adhesive. Examples of the radically polymerizable resin contained in the adhesive 21b include acryl resins, in addition to urethane acryl resins.

As shown in FIG. 5(b), the entire exposed surface of the adhesive 20b is irradiated with the ultraviolet light 50 from a light source lamp such as a metal halide lamp at an integrated light quantity of about 100 to 1500 mJ/cm² (the first irradiation). Thereby, a cation, which serves as an active species, is generated from an initiator contained in the cationically polymerizable resin and a radical, which serves as an active species, is generated from an initiator in the radically polymerizable resin to initiate polymerization, namely, curing of the adhesive 20b. Examples of the initiator commonly contained in the cationically polymerizable resin include a Bronsted acid or a Lewis acid such as aluminum trichloride. The radically polymerizable resin commonly contains an initiator such as an organic peroxide including benzoyl peroxide (BPO), an azo compound including azobisisobutylonitrile (AIBN), or a photo-sensitive molecule which is excited by the action of light or reacts with another molecule to generate a radical. The adhesive 20b contains a rapidly curable and radically polymerizable resin, and the ratio thereof is adjusted to be relatively small as mentioned above. Thus, the adhesive 20b is allowed to have slow curability, and the display panel 10 and the cover substrate 30 are allowed to be bonded to each other after the direct irradiation of a small amount of the ultraviolet light 50. This prevents the adhesive 20b from remaining as an uncured portion at the portion corresponding to the black edge portion 31 of the cover substrate 30. Further, the adhesive 20b contains a relatively large amount of the cationically polymerizable resin. This prevents oxygen from inhibiting the polymerization of the radically polymerizable resin. Thus, an uncured portion is prevented from remaining in the adhesive 20b even in the case of UV irradiation under atmospheric pressure.

As shown in FIG. 5(c), the cover substrate 30 is bonded to the liquid crystal display panel 10 via the adhesive 20b under atmospheric pressure or a reduced pressure at 10 Pa or lower. Then, the cover substrate 30 is pressurized with a pressurizing means, and thereby the liquid crystal display panel 10 and the cover substrate 30 are allowed to have a preferable distance between them. The pressure to be applied is not particularly limited, and may be about 50 kPa, for example. Then, the cover substrate 30 is shifted in a horizontal direction with an alignment means such as a chuck so as to align the liquid crystal display panel 10 and the cover substrate 30.

As shown in FIG. 5(d), the adhesive 20b is again irradiated with the ultraviolet light 50 by a light source lamp such as a metal halide lamp through the cover substrate 30 at an integrated light quantity of about 1000 to 5000 mJ/cm² (the second irradiation), while the liquid crystal display panel 10 and the cover substrate 30 each are held at an appropriate position. Then, the liquid crystal display panel 10 and the cover substrate 30 each are held at the appropriate position until the adhesive 20b is entirely cured (for about 5 minutes). Thereby, the cover substrate 30 is fixed to the liquid crystal display panel 10.

In the same manner as in Embodiment 1, the liquid crystal display module in which the cover substrate 30 is bonded to the liquid crystal display panel 10, a backlight unit, a cabinet, and other components are assembled with one another to provide the display device of the present embodiment.

In the present embodiment, the adhesive 20b contains the rapidly curable and radically polymerizable resin in addition to the cationically polymerizable resin. This shortens the curing time period of the adhesive 20b, that is, the time period of holding the liquid crystal display panel 10 and the cover substrate 30 after the alignment, resulting in better productivity.

As in the case of Embodiment 1, only the first irradiation may be performed and the second irradiation may not be performed in the present embodiment.

### Embodiment 3

The following will describe the display device of Embodiment 3 referring to FIG. 6. The contents of Embodiment 3 overlapping with those of Embodiment 1 are not described here.

The display device of the present embodiment has the same structure as that of Embodiment 1. Further, the adhesive layer of the present embodiment contains a cationically polymerized resin formed by thermal curing. Thus, the adhesive, which is a material of the adhesive layer, of the present embodiment is more rapidly cured by heating. This results in a shorter curing time period of the adhesive, which is a material of the adhesive layer, and better productivity in the present embodiment than in Embodiment 1.

The following will describe a method for producing the display device of Embodiment 3 referring to FIG. 6. FIGS. 6(a) to 6(d) each are a schematic cross-sectional view showing the display device of Embodiment 3 in the production process.

In the same manner as in Embodiment 1, the liquid crystal display panel 10 and the cover substrate 30 having the window portion 32 and the black edge portion 31 are prepared.

As shown in FIG. 6(a) and in the same manner as in Embodiment 1, an adhesive 20c is applied to the polarizing plate 13a of the liquid crystal display panel 10 with the nozzle 40 of an applying apparatus such as a slit coater so that the thickness of the applied adhesive is about 50 to 200 μm. Here, the adhesive 20c is a UV-curable adhesive containing the thermally curable and cationically polymerizable resin. Such an adhesive 21c is not particularly limited as long as it contains a thermally curable and cationically polymerizable resin commonly used in the electronic or optical device field. Examples thereof include a UV-curable resin (Exp MP-48, produced by Dainippon Ink and Chemicals, Corp.). Exp MP-48 is a colorless, transparent urethane resin and has a viscosity of about 1800 cP at 23° C. The thermally curable and cationically polymerizable resin contained in the adhesive 21c is not particularly limited as long as it is usable as adhesive. Examples of the thermally curable and cationically polymerizable resin contained in the adhesive 21c include epoxy resins and urethane resins, in addition to urethane acryl resins.

As shown in FIG. 6(b), the entire exposed surface of the adhesive 20c is irradiated with the ultraviolet light 50 from alight source lamp such as a metal halide lamp at an integrated light quantity of about 100 to 1500 mJ/cm² (the irradiation). Thereby, a cation, which serves as an active species, is generated from an initiator in the cationically polymerizable resin to initiate polymerization, namely, curing of the adhesive 20c. As mentioned here, the cationically polymerizable resin contained in the adhesive 20c commonly contains an initiator such as a Bronsted acid or a Lewis acid including aluminum trichloride. Further, the cationically polymerizable resin has dark reactivity and slow curability, so that the display panel 10 and the cover substrate 30 are allowed to be bonded to each other after the direct irradiation of a small amount of the ultraviolet light 50 to the adhesive 20c. This prevents the adhesive 20c from remaining as an uncured portion at the portion corresponding to the black edge portion 31 of the cover substrate 30. Furthermore, the polymerization of the cationically polymerizable resin is not inhibited by oxygen, so that an uncured portion is effectively prevented from remaining in the adhesive 20c even in the case of UV irradiation under atmospheric pressure.

As shown in FIG. 6(c), the cover substrate 30 is bonded to the liquid crystal display panel 10 via the adhesive 20c under atmospheric pressure or a reduced pressure at 10 Pa or lower. Then, the cover substrate 30 is pressurized with a pressurizing means, and thereby the liquid crystal display panel 10 and the cover substrate 30 are allowed to have a preferable distance between them. The pressure to be applied is not particularly limited, and may be about 50 kPa, for example. Then, the cover substrate 30 is shifted in a horizontal direction with an alignment means such as a chuck so as to align the liquid crystal display panel 10 and the cover substrate 30.

As shown in FIG. 6(d), the liquid crystal display module in which the cover substrate 30 is bonded to the liquid crystal display panel 10 is placed on a hot plate 60. The adhesive 20c is heated at 70° C. to 80° C. (more preferably 50° C. to 60° C.) by the hot plate 60 until the adhesive 20c is entirely cured (for about 2 minutes) (the heating). This accelerates the curing of the adhesive 20c and shortens the curing time period. A heating temperature of higher than 80° C. may deteriorate the polarizing plates 13a and 13b and a retardation film used in the liquid crystal display panel 10.

In the same manner as in Embodiment 1, the liquid crystal display module in which the cover substrate 30 is bonded to the liquid crystal display panel 10, a backlight unit, a cabinet, and other components are assembled with one another to provide the display device of the present embodiment.

In the present embodiment, the adhesive 20c contains the thermally curable and cationically polymerizable resin. This shortens the curing time period of the adhesive 20c, that is, the time period of holding the liquid crystal display panel 10 and the cover substrate 30 after the alignment, resulting in better productivity.

The heating means of the adhesive 20c is not particularly limited as long as it is a common heating means, and examples thereof include an oven. In particular, the heating means of the adhesive 20c is preferably a stage for alignment having a heating function. This allows the adhesive 20c to be heated while the liquid crystal display panel 10 and the cover substrate 30 each are held at an appropriate position. Thereby, the curing of the adhesive 20c is rapidly completed while the liquid crystal display panel 10 and the cover substrate 30 are aligned with high accuracy.

The present invention has been mentioned in detail with reference to Embodiments 1 to 3. Each of the embodiments may be combined so long as the combination use is within the scope of the present invention. For example, the adhesive layer of the present invention may contain a cationically polymerized resin formed by thermal curing and a radically polymerized resin.

The present application claims priority to Patent Application No. 2007-274345 filed in Japan on Oct. 22, 2007 under the Paris Convention and provisions of national law in a designated State, the entire contents of which are hereby incorporated by reference.

### BRIEF DESCRIPTION OF DRAWINGS

FIGS. 1 are a schematic cross-sectional view showing the display device of Embodiment 1. FIG. 1(a) is a whole view; and FIG. 1(b) is an enlarged view showing the area enclosed by the dot line in FIG. 1(a), that is, the vicinity of the end portion of the adhesive layer.

FIG. 2 is a schematic plane view showing the cover substrate of Embodiment 1.

FIG. 3 is a schematic plane view showing the liquid crystal display panel of Embodiment 1.

FIGS. 4(a) to 4(c) each are a schematic cross-sectional view showing the display device of Embodiment 1 in the production process.

FIGS. 5(a) to 5(d) each are a schematic cross-sectional view showing the display device of Embodiment 2 in the production process.

FIGS. 6(a) to 6(d) each are a schematic cross-sectional view showing the display device of Embodiment 3 in the production process.

FIGS. 7(a) to 7(c) each are a schematic cross-sectional view showing the display device of the comparative embodiment in the production process.

FIG. 8 is an enlarged view showing the area enclosed by the dot line in FIG. 7(c), that is, the vicinity of the end portion of the adhesive layer in the display device of the comparative embodiment.

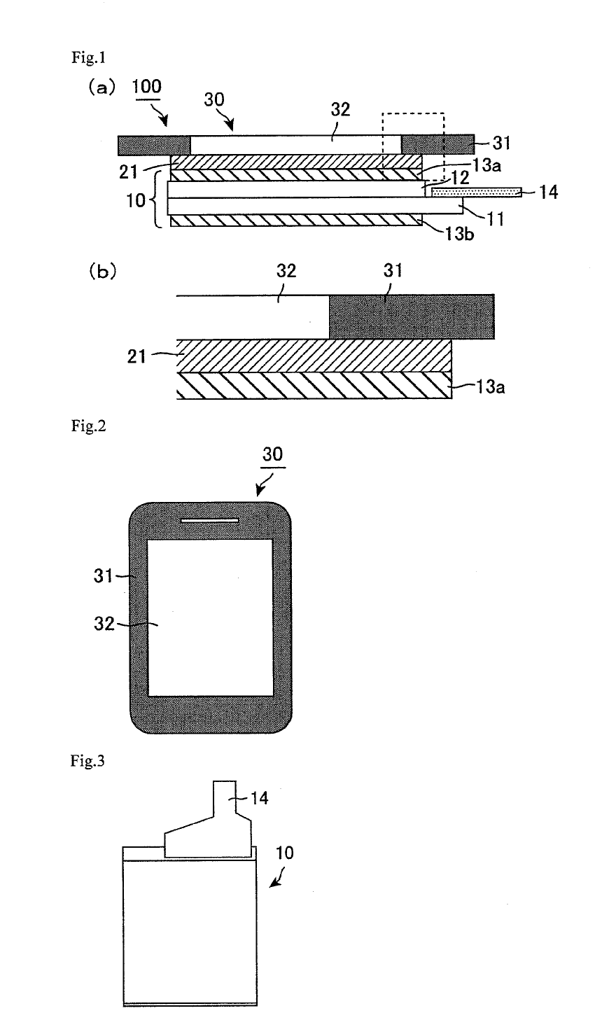

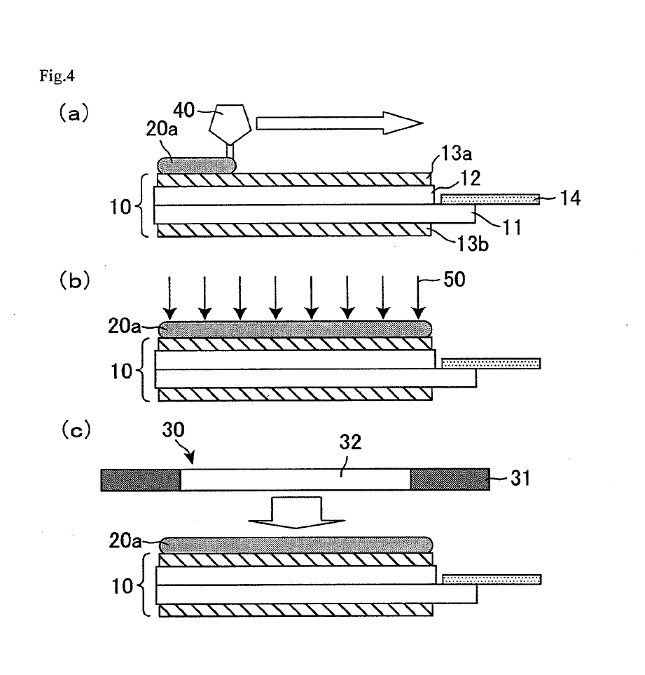

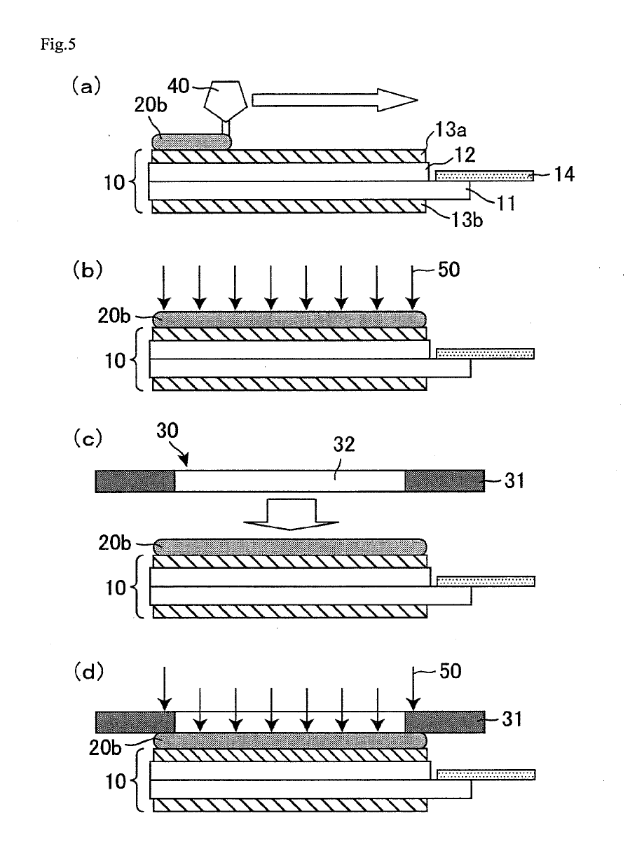

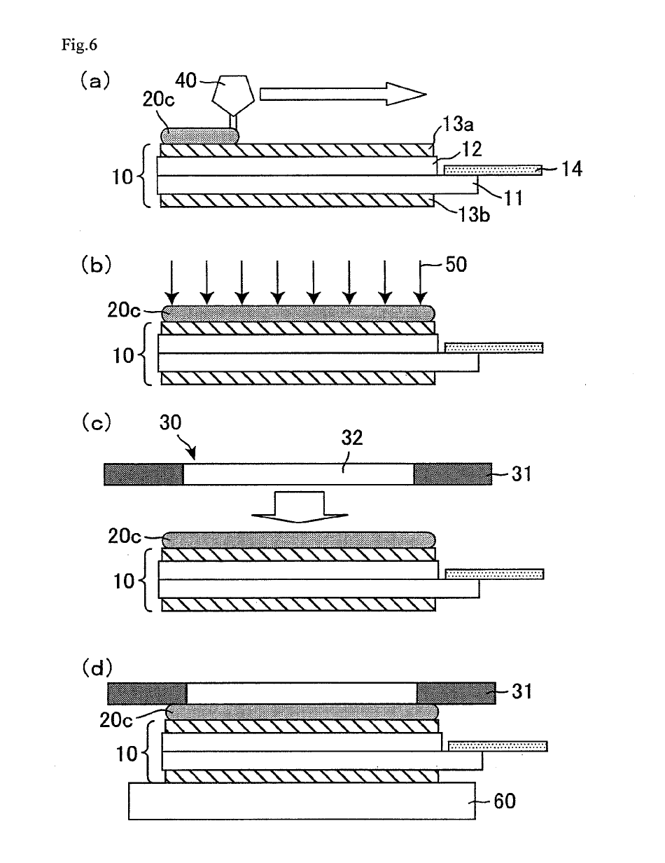

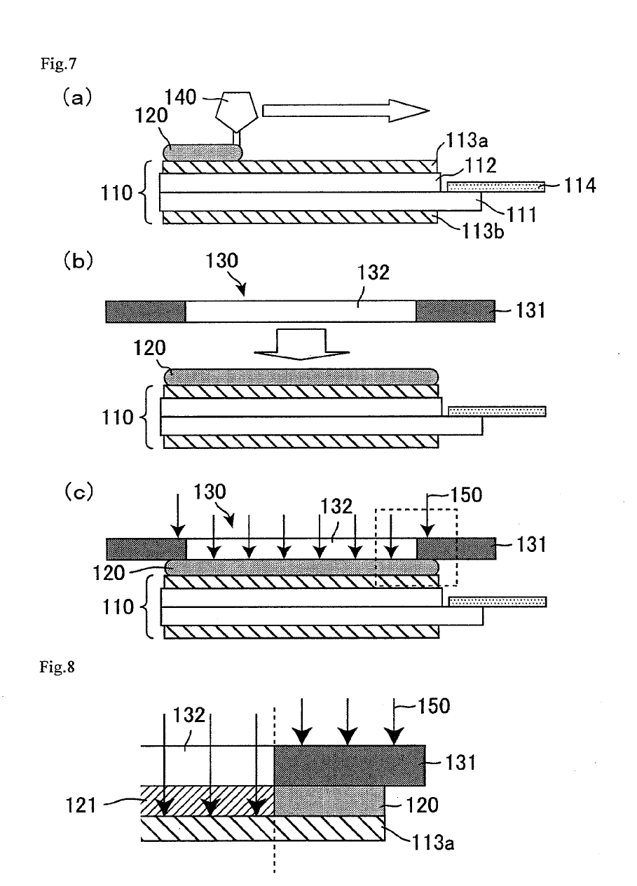

### EXPLANATION OF NUMERALS AND SYMBOLS

10, 110: Liquid crystal display panel
11, 111: TFT array substrate
12, 112: CF substrate
13a, 13b, 113a, 113b: Polarizing plate
14, 114: FPC substrate
20a, 20b, 20c, 120: Adhesive (uncured adhesive)
21, 121: Adhesive layer (cured adhesive)
30, 130: Cover substrate
31, 131: Black edge portion (light shielding portion)
32, 132: Window portion (light transmitting portion)
40, 140: Nozzle
50, 150: Ultraviolet light
60: Hot plate
100: Display device

1. A display device, comprising:
a display panel;
a substrate disposed on a display side; and
an adhesive layer via which the display panel and the substrate are bonded to each other,
wherein the adhesive layer contains a cationically polymerized resin.

2. The display device according to claim 1,
wherein the adhesive layer is colorless and transparent.

3. The display device according to claim 1,
wherein the adhesive layer has a refractive index corresponding to a refractive index of a member adjacent to the adhesive layer.

4. The display device according to claim 1,
wherein the adhesive layer further contains a radically polymerized resin.

5. The display device according to claim 1,
wherein the cationically polymerized resin is formed by thermal curing.

6. The display device according to claim 1,
wherein the substrate has a light shielding portion at an area to which the adhesive layer is attached.

7. The display device according to claim 1,
wherein the substrate is a cover substrate.

8. The display device according to claim 1,
wherein the display panel is a liquid crystal display panel or an organic electroluminescent display panel.

9. A method for producing the display device according to claim 1, comprising:
applying an adhesive, which is a material of the adhesive layer, to at least one of the display panel and the substrate;
irradiating light to the adhesive; and
bonding the display panel and the substrate to each other via the light-irradiated adhesive.

10. The method for producing the display device according to claim 9, further comprising
irradiating light to the adhesive again after bonding the display panel and the substrate to each other.

11. The method for producing the display device according to claim 10, comprising:
the first irradiation step of light to the adhesive applied to at least one of the display panel and the substrate;
the bonding step of the display panel and the substrate to each other after the first irradiation step; and
the second irradiation step of light to the adhesive again after the bonding step.

12. The method for producing the display device according to claim 9, further comprising
heating the adhesive after bonding the display panel and the substrate to each other.

13. The method for producing the display device according to claim 12, comprising:
the first irradiation step of light to the adhesive applied to at least one of the display panel and the substrate;
the bonding step of the display panel and the substrate to each other after the first irradiation step; and
the heating step of the adhesive after the bonding step.
